(19) United States
(12) Patent Application Publication
(10) Pub. No.: US 2019/0359482 A1
(43) Pub. Date: Nov. 28, 2019

(54) METHOD AND APPARATUS FOR ETCHING A SUBSTRATE

(71) Applicants: INSTITUT NATIONAL DE LA SANTÉ ET DE LA RECHERCHE MÉDICALE (INSERM), Paris (FR); UNIVERSITÉ D'AIX-MARSEILLE, Marseille (FR); CENTRE NATIONAL DE LA RECHERCHE SCIENTIFIQUE (CNRS), Paris (FR)

(72) Inventors: Jérôme BELOUGNE, MARSEILLE CEDEX 9 (FR); Céline CAILLARD, ROSCOFF (FR)

(21) Appl. No.: 16/476,669

(22) PCT Filed: Jan. 5, 2018
(86) PCT No.: PCT/EP2018/050270

§ 371 Date: Jul. 9, 2019

(30) Foreign Application Priority Data
Jan. 9, 2017 (EP) 17305019.6

(51) Int. Cl. B81C 99/00; H01F 7/02; B81C 1/00

(52) U.S. Cl. CPC B81C 99/0025; H01F 7/0242; B81C 2201/0159; B81C 2201/0133; B81C 1/00111

(57) ABSTRACT

The invention relates to the field of method of etching a substrate (W), in particular a wafer, in order to produce a grid of micro-protrusion. Such grid of micro-protrusion is generally made using UV photolithography followed by wet and chemical engraving with an etching solution. Most of the currently available methods do not lead to an even attack of the wafer surface by the etching solution because the reaction produces a release of micro-bubbles which, if not properly evacuated, disturb the etching process. In the present invention, substrate(s) (W) are disposed on a magnetic supporting device (1) which is driven in rotation in the etching solution via a magnetic agitator external to the etching solution, so that the magnetic supporting device (1) causes the substrate to rotate at least in a same direction the magnetic supporting device (1). The present invention makes it possible to obtain substrates with good homogeneity.

### BACKGROUND

Technologies have been developed to pierce or make permeable numerous worms' cuticle in an easy and quick way to transfect DNA into the germ line.

A species of worms commonly used is C.elegans. These worms present a typical size of about 1 mm in length and ⅓ mm in diameter.

One laboratory injection equipment of genetic material commonly used in order to obtain transgenic worms is constituted by a microscope, a micro-injector and a micromanipulator. Microinjection requires long and tedious manual handling and much expertise is essential for the sample preparation, handling and injection equipment. Besides, the injection equipment is expensive.

Another known type of device for microinjection is a grid of micro needles, referred to as a “bed of nails”. This tool allows to pierce/make permeable numerous worms' cuticle in a very easy and quick way in order to apply electroporation and transfect DNA into the germ line. This tool allows wounding a high number of worms in few seconds.

In laboratory, such a device is generally made on a silicon wafer (Si/SiO₂) using UV photolithography followed by wet and chemical engraving.

During the wet and chemical engraving, the wafer is often held by a fixed support. Then the assembly of the wafer and the support is introduced in a beaker containing an ad hoc solution of KOH with experimental conditions that allow attack of the surface layer of the wafer according to the laws of crystal physics.

The beaker is placed in a bain-marie on a heating agitator. Commonly used agitator in laboratory scale comprises a coil system that is arranged under the beaker for driving a magnetic agitating member, in particular a magnetic rod, inside the beaker. The KOH solution is thus continuously-mixed by the magnetic rod. However, the reaction produces a release of micro-bubbles which, if not properly evacuated, disturb the etching process. This may lead to an uneven attack of the wafer surface by the KOH solution and may degrade severely the precision of etching.

Numerous other solutions have been proposed to etch wafers, most often at an industrial level for the semi-conductor industry.

JP01201490 discloses rotating back and forth wafers immerged in an etching solution.

CN 2058786U teaches using a wafer holder for rotating a wafer in an opposite direction from an agitating member in an etching liquid.

JP 2001-15482 describes an etching device in which a plurality of vertically disposed wafers are in contact, at the bottom of their peripheral edge, with a magnetic rod. The wafers and the magnetic rod are immersed in an etching solution. A magnetic device situated outside the etching solution drives in rotation the magnetic rod and thus the wafers in a rotational movement in an opposite direction relative to that of the magnetic rod.

Some of these devices are quite complex and expensive and inappropriate at the laboratory scale where only a few wafers need to be etched from time to time.

There thus remains a need for improving devices for etching wafers at the laboratory scale.

### SUMMARY OF THE INVENTION

In order to further improve the quality of etching, exemplary embodiments of the present invention provide a method of etching a substrate, in particular a wafer, in order to produce a grid of micro-protrusions, the method comprising disposing the substrate on a magnetic supporting device, and driving, in an etching solution, the magnetic supporting device in rotation via a magnetic agitator external to the etching solution so that the magnetic supporting device causes the substrate to rotate at least in a same direction as the magnetic supporting device.

The invention makes it possible to better evacuate, from the surface of the substrate, undesired elements produced by the chemical reaction of etching, such as micro bubbles, and thus improves the quality of the etched surface.

The supporting device and the substrate may be disposed, during the etching, in any container appropriate for containing the etching solution, such as a beaker. The magnetic agitator is preferably disposed under a container containing the etching solution.

The substrate is preferably a planar substrate.

The substrate may be of a largest dimension ranging from 2.5 to 10 cm.

According to one exemplary embodiment of the invention, a plurality of substrates is disposed simultaneously on the supporting device.

The substrate(s) may be disposed on the magnetic supporting device in a static manner, i.e., the substrate(s) may not move relative to the magnetic supporting device before and/or during the etching process.

Alternatively, the substrate(s) may be disposed on the magnetic supporting device in a moveable manner, i.e., the substrate(s) may perform relative movement with regard to the magnetic supporting device while remaining carried by or immobilized thereon. This may allow to set the orientation of the substrate relative to the magnetic supporting device and to help finding the orientation that leads to the best results of the etching process.

The magnetic supporting device may comprise at least one removable part that can be withdrawn from the etching solution without withdrawal of the substrate(s) to be etched. The method of etching a substrate may comprise disposing a test substrate on the one or each removable part. In this way, the progress of the etching can be known by withdrawing and analyzing the test substrate from the etching solution, preferably on a regular basis during the etching process.

The substrate may rotate while fixed on the magnetic support device about an axis perpendicular to the axis around which the magnetic supporting device rotates.

Exemplary embodiments of the invention also provide a system comprising:

a magnetic agitator,

a magnetic supporting device configured for holding at least one substrate to be etched in an etching solution, in particular a wafer, in a predefined configuration relative to the magnetic supporting device, so that when the magnetic supporting device is driven in rotation by the magnetic agitator the substrate rotates in a same direction as the supporting device.

For example, if the magnetic supporting device is driven clockwise in rotation within a beaker or any other container containing the etching solution by the magnetic agitator, the substrate also rotates clockwise relative to the beaker. Similarly, if the magnetic supporting device is driven anti-clockwise relative to the beaker, the substrate rotates anti-clockwise relative to the beaker. The movement of the substrate may comprise further motion components, and may be a complex movement comprising a general rotation together with the support and a further movement.

The invention allows using a magnetic agitator commonly used in laboratory for driving in rotation a magnetic rod placed in a beaker. Thus, the invention makes it possible to achieve good etching results in a simple manner. This is advantageous for making etched wafers at the laboratory scale.

Preferably, the supporting device comprises a discrete magnet, for example a magnetic rod.

In a variant, the supporting device comprises a plurality of discrete magnets.

Exemplary embodiments of the invention further provide a magnetic supporting device comprising:

a body,

at least one holding member for holding at least one substrate in a predefined configuration relative to the body,

at least one magnet fixed relative to the body.

The magnetic supporting device may be configured for holding, individually or simultaneously, substrates of different dimensions.

The magnetic supporting device may comprise a plurality of magnets fixed to the body and/or to the holding member.

The holding member(s) may be fixed or movable relative to the body of the magnetic supporting device.

A movable holding member(s) may allow variation of an orientation of the substrate(s) before the etching process.

The holding member(s) may rotate around at least one axis, for example around an axis perpendicular to the axis around which the body of the magnetic supporting device rotates during the etching process.

The holding member(s) may be configured to grip the substrate(s) in various manners.

The holding member(s) may comprise a base element for supporting the at least one substrate and gripping means configured for holding the at least one substrate onto the base element.

The holding member(s) may comprise gripping means for holding substrates of different dimensions.

A holding member may comprise jaws that contact opposite faces or edges of a substrate.

The holding member(s) may comprise portions projecting above the body. This may allow creating more available space for positioning the substrate(s) in the desired orientation relative to the body, and may allow to increase the number and/or the size of substrate(s) to be etched.

Preferably, the holding member(s) are configured so that the substrate(s) held by the holding member(s) are not in contact with the magnet(s) or the body.

The body may comprise a ring-shaped element at its periphery and a central element formed integrally with the ring-shaped element and extending along a diameter of the body. The central element may comprise holes for accommodating corresponding permanent magnets.

The base element may comprise two arms intersecting at their mid-length and forming a cross concentric with the body, the length of each arm being preferably substantially equal to the outer diameter of the ring-shaped element.

Each half of an arm may comprise a hole for receiving a corresponding permanent magnet. The holes on a same arm are preferably positioned symmetrically with regard to the center of the base element.

The body may comprise a wall portion comprising concentric upper and lower rings.

The base element may be fixed to the upper ring, for example by friction. The base element may be movable relative to the upper ring. In a variant, the base element is molded integrally with the upper ring.

The ring-shaped element may be received in the lower ring, for example in a groove thereof.

In a variant, the wall portion comprises a central bar, extending along a diameter of the lower ring. The central bar may comprise holes, for example in the number of two, for receiving corresponding permanent magnets. In this case, the presence of the ring-shaped element and the central element can be omitted.

The holding member may comprise a wafer support configured for being fixed to the base element, for example by magnetic forces, and to which the wafer is fixed.

The wafer support may have a cross-shaped body comprising two arms of equal length. Magnets may be fixed to a bottom surface of the wafer support. These magnets are preferably situated on the wafer support so as to face corresponding magnets of the base element when the wafer support is superposed to the base element.

In a variant, the wafer support is fixed directly to the upper ring,

The wafer support may be fixed by magnetic force or by friction.

The magnetic supporting device may comprise at least one removable part that can be withdrawn from the etching solution during etching of the substrate(s) and configured for holding a test substrate.

The one or each removable part may comprise a handle and a socket attached at a lower end thereof, the test substrate being disposed on the socket.

The one or each removable part may comprise at least one magnet, for example two, received in the socket. An attractive force between the magnets present respectively on the removable part(s) and the base element allows the removable part(s) to be driven in rotation by the magnetic agitator simultaneously with the body.

The removable part(s) may comprise each a gripping part, at a free end of the handle, for facilitating gripping of the removable part(s) during their withdrawal. The removable part(s) may comprise respective identification elements, preferably of different shape. The identification elements may be arranged above the gripping parts. This allows identification of the test substrate(s) during the etching process.

The body and/or the holding member(s) may comprise a plastic material, for example a polyolefin or polytetrafluoroethylene, or any other material which is inert to the etching solution.

Commonly used etching solutions include, among other, strong acid or basic solutions, for example an aqueous solution of KOH heated at about 75° C.

Specific embodiments of the invention will now be described in some further detail with reference to and as illustrated in the accompanying figures. These embodiments are illustrative only, and not meant to be restrictive of the scope of the invention.

### DETAILED DESCRIPTION OF THE ILLUSTRATED FIGURES

FIG. 1 shows a laboratory system of prior art for etching a substrate;

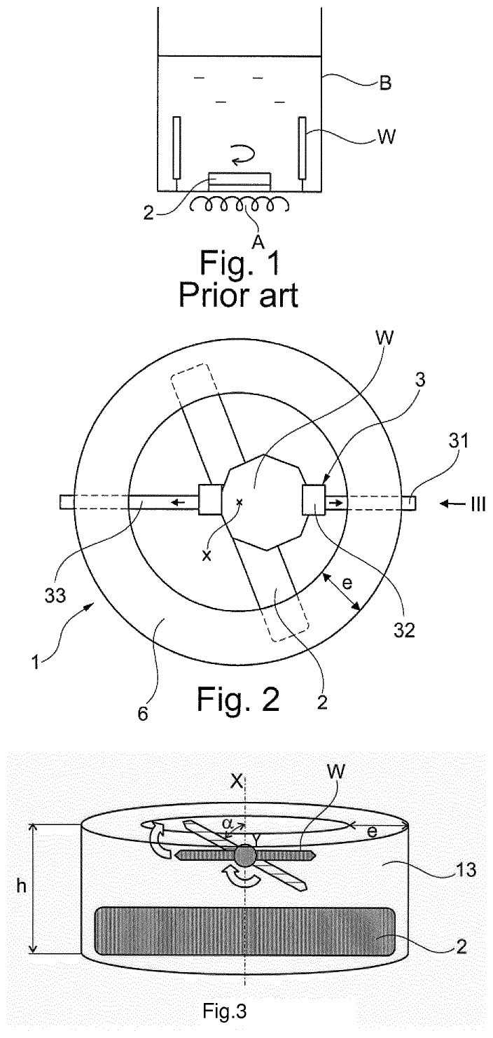

FIG. 2 is a schematic view from above of an embodiment of a magnetic supporting device, made in accordance with the present invention;

FIG. 3 is a side view of the device of FIG. 2 along the arrow III;

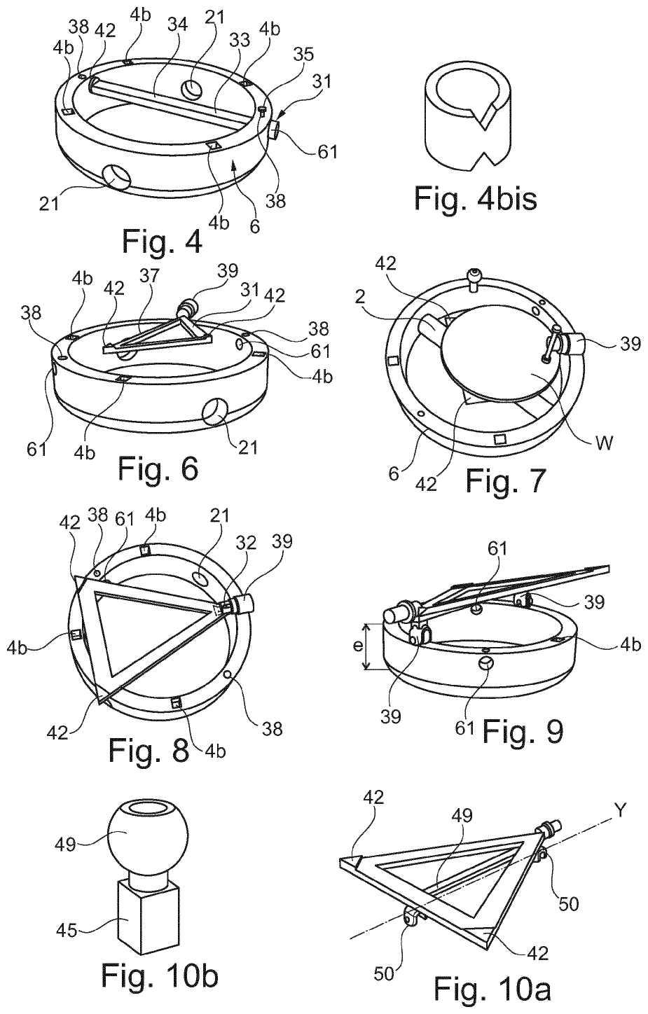

FIG. 4 is a perspective view of the device of FIG. 2;

FIG. 4bis shows some details of the holding member of FIG. 2;

FIGS. 6 to 9 illustrate in a schematic way variants of a magnetic supporting device made in accordance with the present invention;

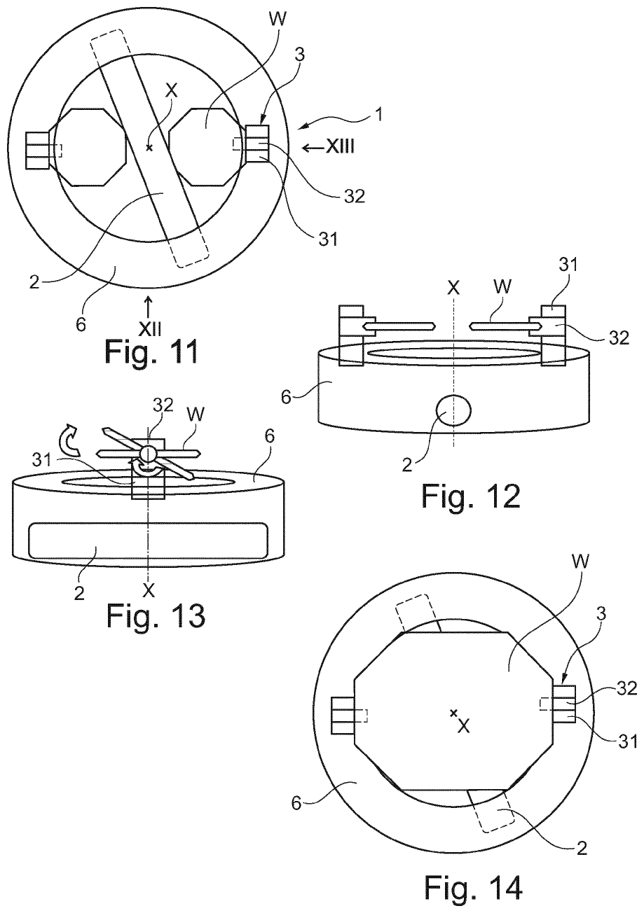

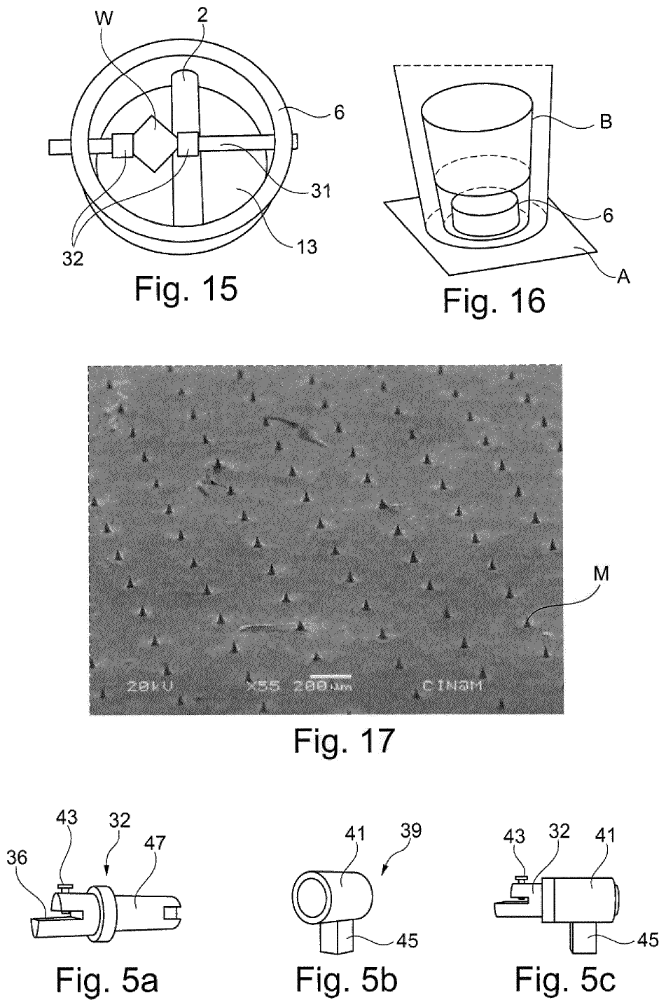

FIGS. 5(a) to 5(c) show some details of the gripping element of the magnetic supporting device of FIG. 6;

FIGS. 10(a) and (b) show details of FIG. 9;

FIG. 11 illustrates a variant of a magnetic supporting device made in accordance with the present invention;

FIG. 12 is a side view of the device of FIG. 11 along arrow XII;

FIG. 13 is a side view of the device of FIG. 11 along arrow XIII;

FIG. 14 illustrates using the magnetic supporting device of FIG. 11 for etching a single wafer;

FIG. 15 shows a variant of a magnetic supporting device made in accordance with the present invention;

FIG. 16 shows a system made in accordance with the present invention;

FIG. 17 shows a wafer obtained by a method according to the present invention;

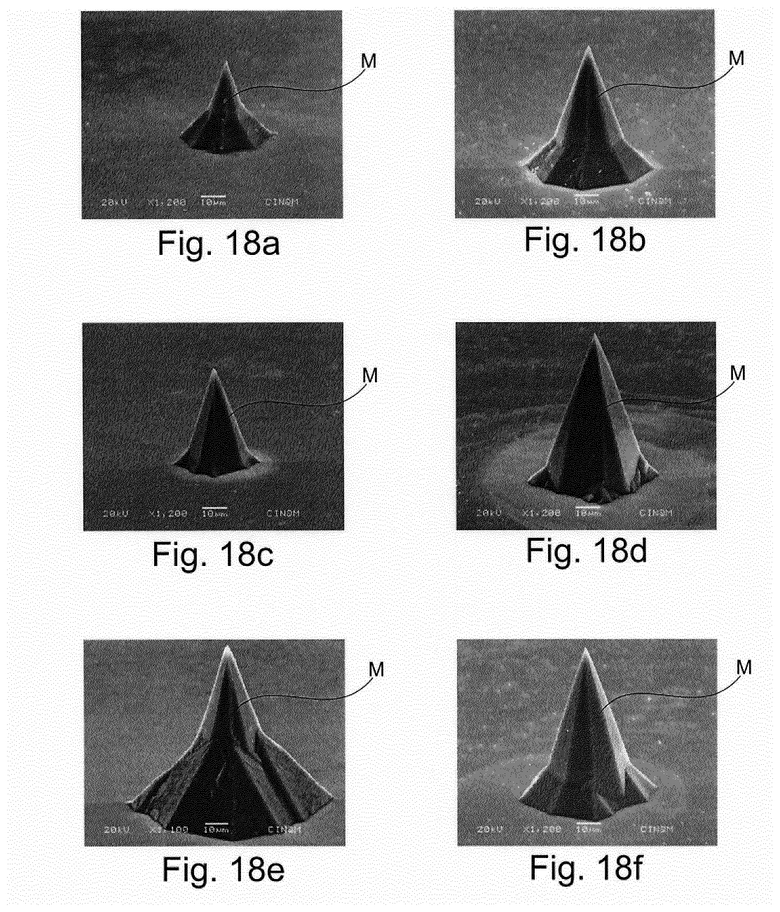

FIGS. 18 (a) to (f) are electronic microscope pictures of six examples of micro-structures obtained by an etching method in accordance with the present invention;

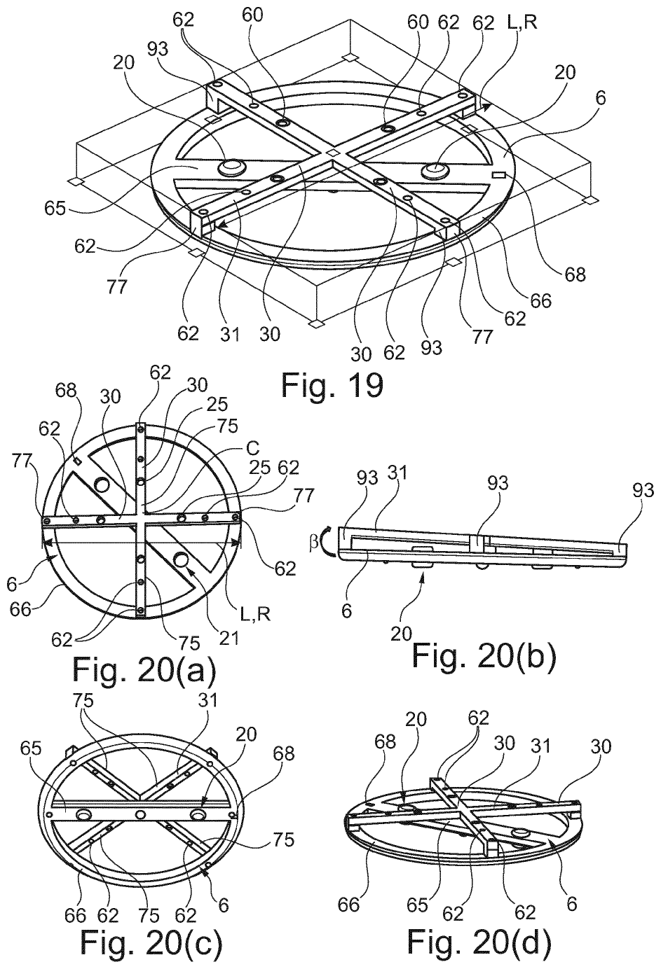

FIG. 19 shows a variant of a magnetic supporting device made in accordance with the present invention;

FIGS. 20 (a) to (d) are different views of the device of FIG. 19;

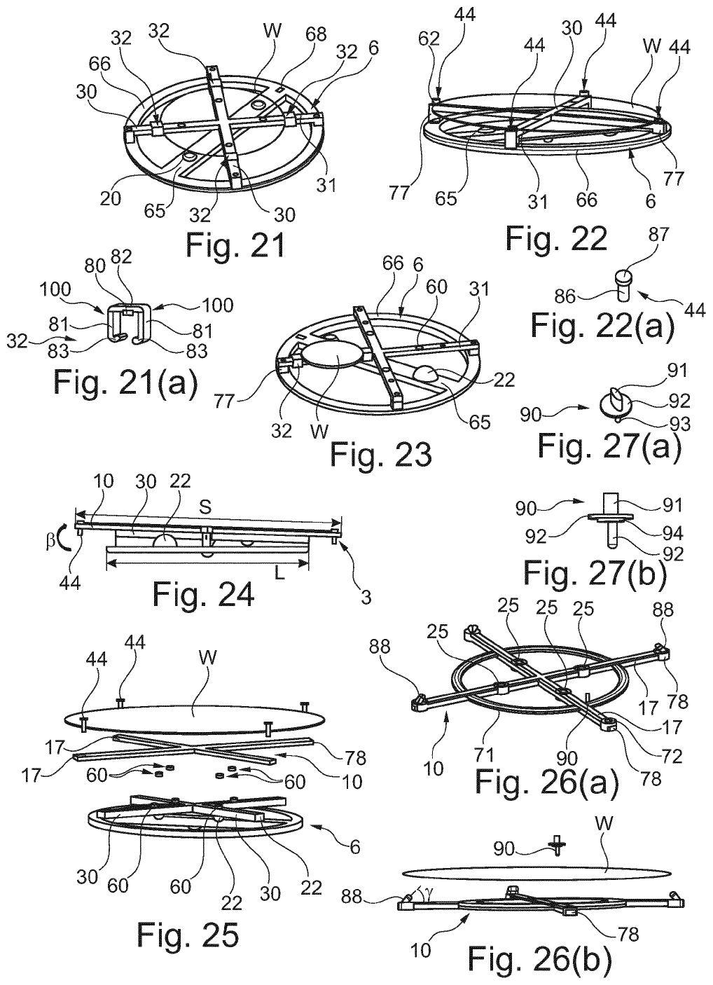

FIGS. 21 to 24 illustrate using the device of FIG. 19 for holding different substrates;

FIG. 25 is an exploded view of the device of FIG. 24;

FIGS. 26(a) and (b) are views of a variant of the device of FIG. 25;

FIGS. 27(a) and (b) shows a detail of the gripping element of the device of FIG. 26;

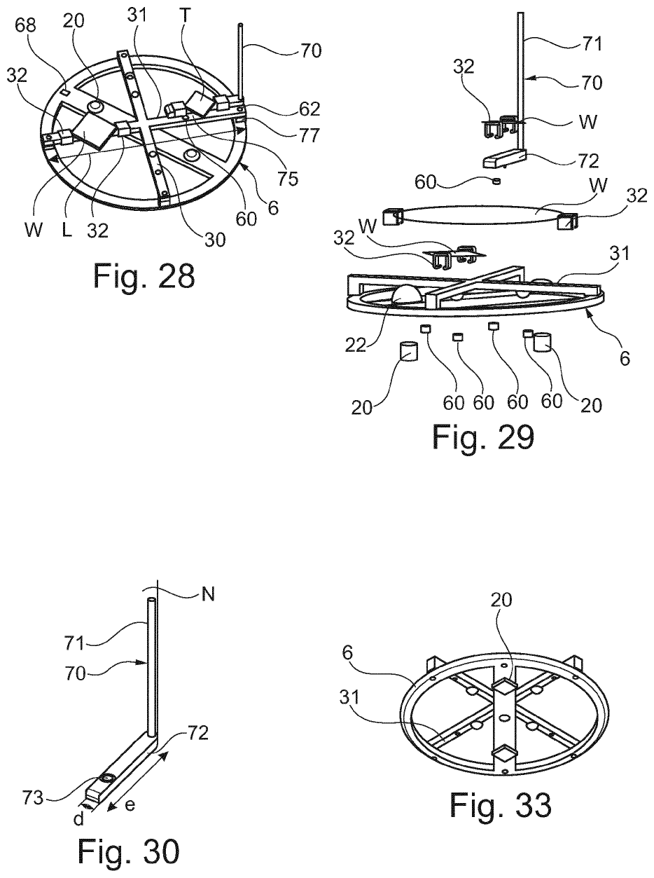

FIGS. 28 and 32 show a variant of a magnetic supporting device made in accordance with the present invention;

FIG. 29 is an exploded view of a variant of the device of FIG. 28;

FIG. 30 shows the removable part;

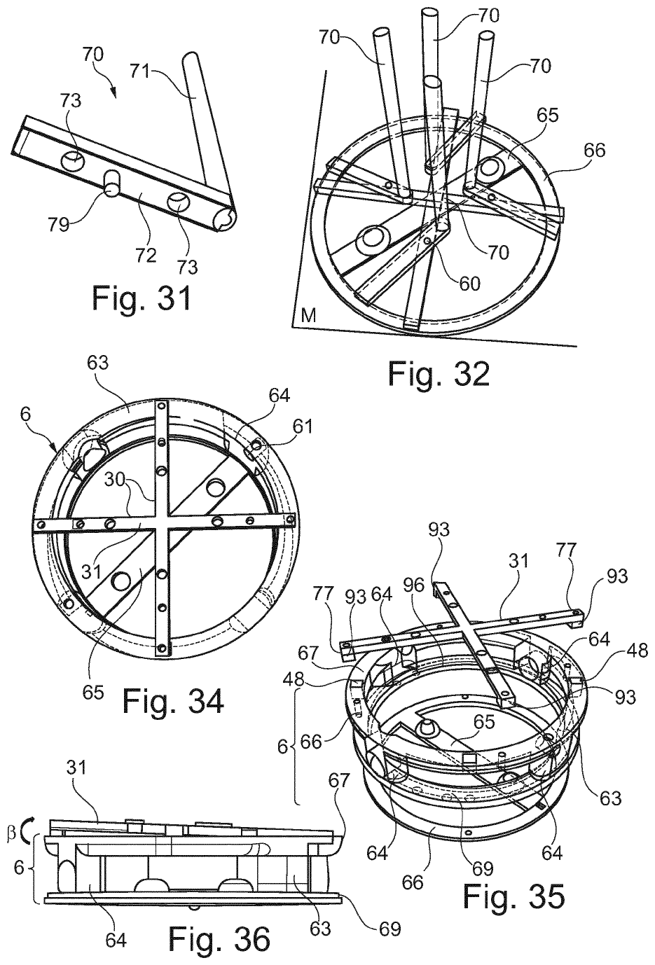

FIG. 31 shows a variant of the removable part of FIG. 30,

FIG. 33 shows a variant of the magnetic device of FIG. 19,

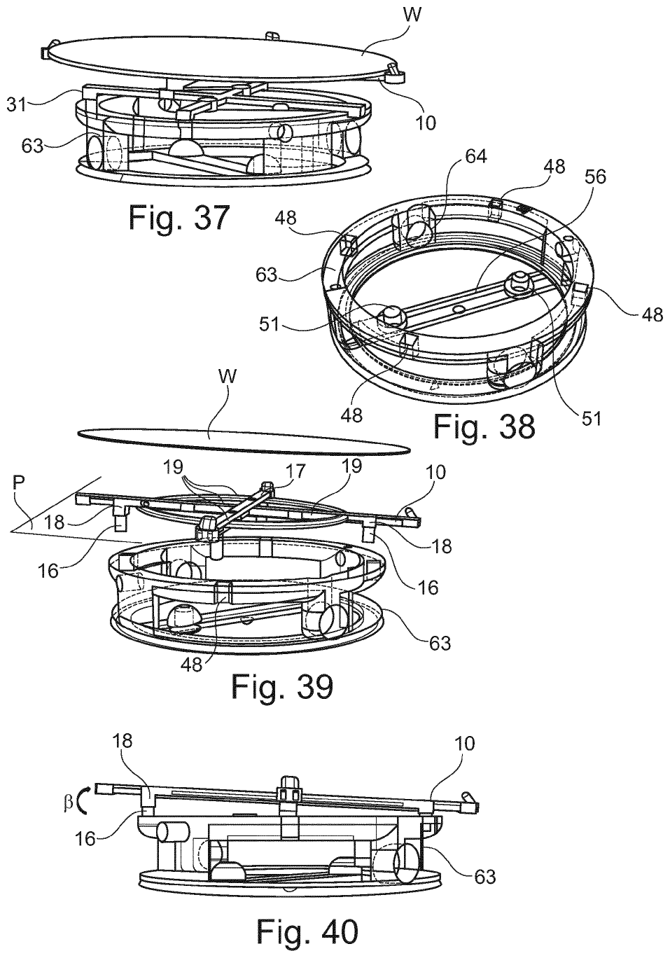

FIGS. 34 to 37 show a variant of the magnetic device of FIG. 19,

FIGS. 38 to 40 show a variant of the magnetic device of FIG. 19,

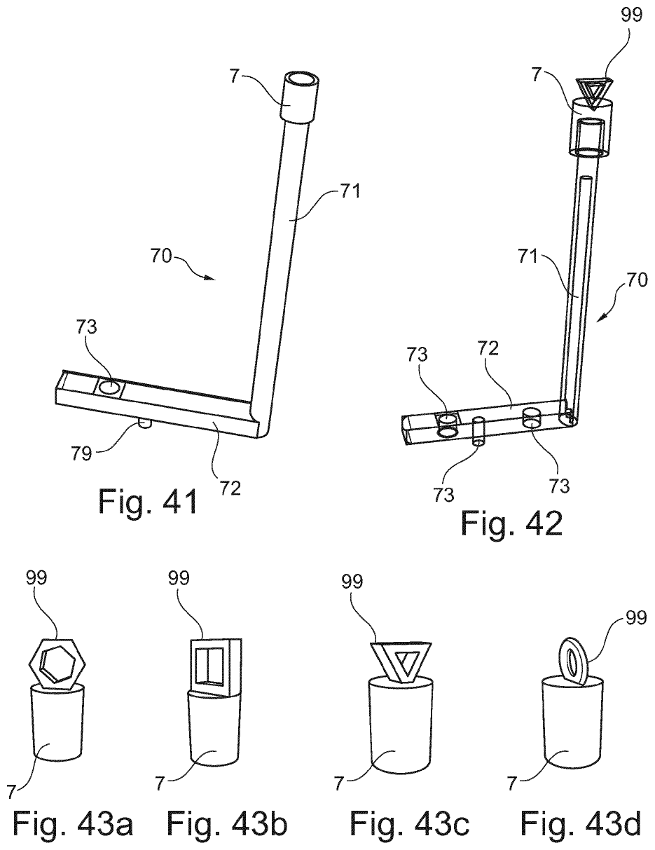

FIGS. 41 and 42 show variants of the removable parts of FIG. 31,

FIGS. 43(a) to (d) show variants of the gripping part,

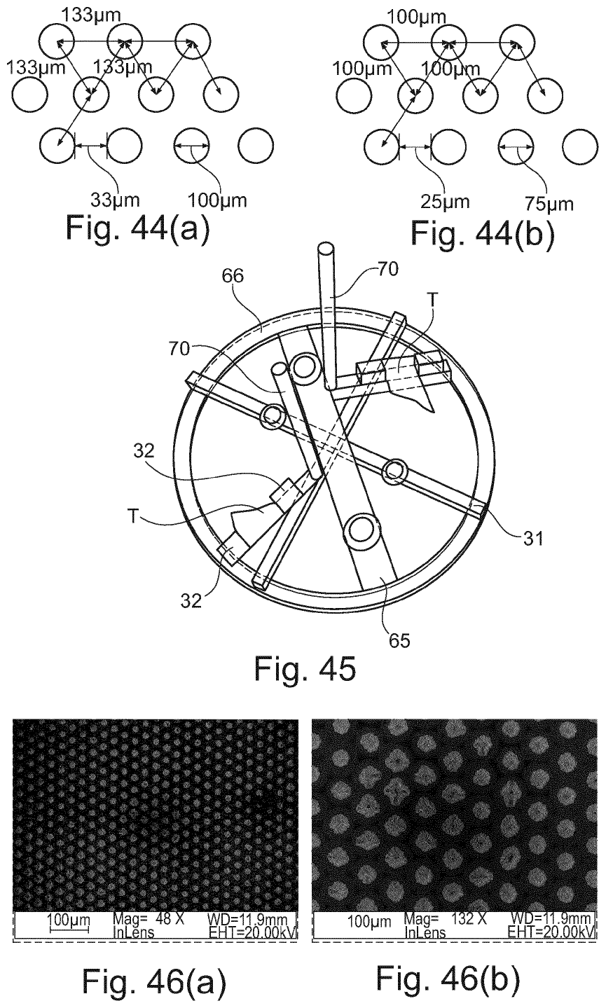

FIGS. 44(a) and (b) illustrate patterns of mask using in UV photolithography,

FIG. 45 shows a variant of a magnetic supporting device made in accordance with the present invention,

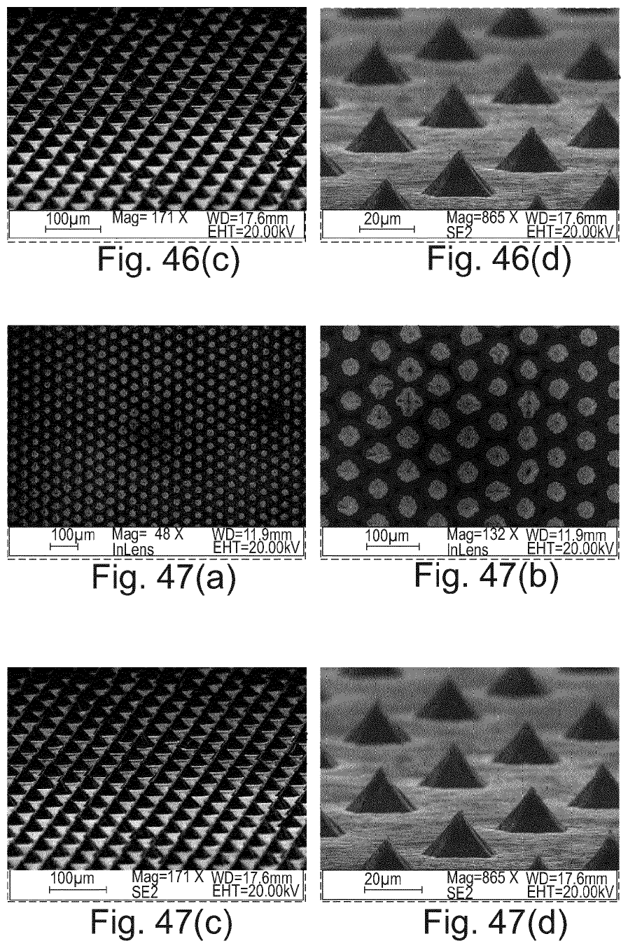

FIGS. 46(a) to (d) and FIGS. 47(a) to (d) are electronic microscope pictures of two examples of micro-structures obtained by using the device of FIG. 45.

In the prior art, etching of a silicon wafer W at a laboratory scale was commonly performed by a system as illustrated in FIG. 1.

The wafers W are placed, for example vertically as illustrated, in a beaker B comprising an etching solution, for example a heated solution of KOH.

A magnetic rod 2 is disposed in the beaker B, which is placed onto a magnetic agitator A. The agitator A drives the magnetic rod 2 in rotation inside the beaker B, thus stirring the etching solution while the wafers W are being etched.

A magnetic supporting device 1 made in accordance with the invention may comprise as illustrated in FIGS. 2 to 4, a body 6, at least one holding member 3 and a magnetic rod 2.

The body 6 may be of a ring shape around an axis X. This axis may be an axis of symmetry for the body 6. The body 6 may comprise respective holes and/or housings for receiving corresponding holding member(s) 3. Preferably, the body 6 comprises holes and/or housings for receiving holding member(s) 3 of different types. This may allow wafers W of different sizes to be held by the supporting device 1.

The magnetic rod 2 may be fixed to the body 6 along a diameter thereof. For example, the body 6 comprises two diametrically opposite holes 21 into which the magnetic rod 2 is inserted, so that rotation of the magnetic rod 2 drives in rotation the body 6 around the axis X.

An external agitator A is used to drive the magnetic supporting device 1 in rotation around the axis X.

The holding member 3 rotates in a same rotational movement as the body 6.

In the embodiments of FIGS. 2 to 4, the holding member 3 comprises a base element 31 in the form of a rod 33, and two gripping members 32 for holding the wafer W. Each gripping member 32 may comprise a sleeve as illustrated in FIG. 4bis that can slide with friction along the rod 33. The sleeve comprises notches at respective ends thereof for gripping the wafer W.

The body 6 may comprise as shown two diametrically opposite holes 61 situated close to the upper face thereof for insertion of the rod 33.

At least one end of rod 33 may project radially outside the body 6. This allows a user to turn the rod 33 around its longitudinal axis to set the wafer W with the desired orientation relative to the body 6. In the illustrated embodiment, the two opposite ends of the rod 33 are inserted in respective holes 61. In a variant not illustrated, the rod 33 is held in cantilever fashion with only one end thereof inserted in a corresponding hole 61.

Preferably, the magnetic rod 2 is offset with regard to the holding member 3 along the axis X of the body 6. The magnetic rod 2 is situated beneath the holding member 3 so that it does not come into contact with the wafer W to be etched.

The wafer W may have in front view a polygonal, for example square shape, as illustrated in FIG. 2. The wafer W may be held at opposite edges by the gripping members 32.

In a variant, the wafer W may have other shapes, such as for example a circular outline as illustrated in FIG. 7.

The rod 33 may comprise a planar top surface 34 to provide support for the rear face of the wafer W, as illustrated in FIG. 4, and for preventing gripping members 32 to rotate relative to the rod 33.

The rod 33 may be tightened onto the body 6 at the desired orientation by at least one screw 35 introduced in a corresponding fixing hole 38.

In the embodiment of FIGS. 2 to 4, the device 1 is configured so that the holding member 3 does not project above the body 6.

In a variant, the base element 31 projects above the body 6. Having the base element 31 projecting above the body 6 may allow creating more available space for positioning the wafer W, thus increasing the number and/or the size of wafers to be etched. This may also allow the wafers to be etched simultaneously on both faces.

In the variants illustrated in FIGS. 6 to 8, the base element 31 comprises a frame 37, for example of a polygonal shape, such as a triangular shape.

This shape of the base element 31 may provide more supporting surface in contact with the wafer and may improve the stability of the wafer W relative to the base element 31 during the etching.

The base element 31 may comprise stops 42 for holding the wafer W at its periphery.

Preferably, the size of the base element 31 is chosen to match that of the wafer W to be etched.

The frame 37 may not extend beyond the periphery of the body 6 as illustrated in FIGS. 6 and 7. In a variant, the frame 37 extends beyond the periphery of the body 6, as illustrated in FIG. 8.

The diameter of the body 6 may be chosen as a function of the size of the wafer W to be etched and may range between 75 and 100 mm, for example.

The thickness e of the body may lie between 0.7 mm and 10 mm, for example. The height h of the body 6 may range from 15 mm to 30 mm.

During the etching process, the main faces of the wafers W may be oriented perpendicular or oblique to the axis X of the body 6.

The holding member 3 may comprise a rotational support 39 allowing setting the orientation of the wafer W about an axis Y perpendicular to the axis X of the body 6. The axis Y is for example parallel to a diameter of the body 6.

The rotational support 39 may be configured so that an angle a between the upper face of the wafer W and the axis X of the body 6 lies between 0° and 20°, as shown in FIG. 3.

The base element 31 may be frictionally held by the rotational support 39. The gripping element 32 may comprise next to the rotational support 39 a jaw made by a slot 36 into which the wafer W is introduced and a clamping screw 43 for immobilizing the wafer W in the slot 36, as shown in FIG. 5(a).

The rotational support 39 may comprise a cylindrical sleeve 41 defining a bearing for a tip 47 of the gripping member 32. The sleeve 41 is connected to the body 6 via a stem 45 fitted into a corresponding housing 46 opening out on the upper face of the body 6. The body 6 may comprise four housings 46, disposed equally around the axis X of the body 6. For example, as shown, the diametrically opposite holes 21 for insertion of the magnetic rod 2, the diametrically opposite holes for insertion of the rod 33 and the housings 46 may be equally spaced around the axis X of the body.

In the embodiment of FIGS. 6-8, the frame 37 is held in cantilever fashion.

In the variant of FIG. 9, the frame 37 is held at two opposite locations by a pair of rotational supports 39 each fixed in a corresponding housing 46. The rotational supports each comprise a truncated sphere 49 connected to the body 6 via a stem 45 as illustrated in FIG. 10(b). The base element 31 comprises a pair of clevis 50 mounted on the supports 39.

The cooperation between the gripping members 32 and the rotational supports 39 allows rotation of the wafer W relative to the body 6 around an axis Y perpendicular to the axis X of the body 6 in the predefined range.

In a variant not illustrated, the holding member 3 does not comprise a frame for supporting the wafers. For example, in case of wafers of small size, the wafers may be held in the slot 36 of the gripping member 32. The holding member 3 may not comprise a frame.

In the variant illustrated in FIG. 11, the magnetic supporting device 1 comprises two diametrically opposed holding members 3, each of which holds a wafer W in a predefined position relative to the body 6. Each holding member 3 comprises for example a rotational support 39 and a gripping member 32 as illustrated in FIGS. 5 (a) to 5(c).

The body 6 may receive thanks to the housings 46 up to four such holding members.

Preferably, the wafers W are disposed on the body 6 in a manner that the wafers are not in contact with each other.

Preferably, the wafers W do not overlap, when viewed from above along the axis X, as illustrated in FIG. 11.

The gripping elements 32 may be configured for disposing the wafers W at a same height along the axis X of the body 6.

In a variant, the gripping elements 32 are configured for holding the wafers W at different heights along the axis X.

In the embodiment shown in FIG. 14, a single wafer W is held on two opposite ends by the gripping members 32 of the magnetic supporting device of FIG. 11. In this case, a wafer W of a larger surface can be treated.

The body 6 may be closed at its lower end by a bottom wall 13, as illustrated in FIG. 15.

To use a magnetic supporting device made in accordance with the invention, one attaches the wafer W with the gripping means and places the assembly in a beaker B containing the etching solution, for example a solution of KOH as shown in FIG. 16. The beaker B is placed on the magnetic agitator A, as shown. The magnetic agitator A drives the device in rotation, with the wafer W.

In the variant shown in FIG. 19, the body 6 comprises a ring-shaped element 66 at its periphery and a central element 65 formed integrally with the ring-shaped element 66 and extending along a diameter of the body 6. As illustrated in FIGS. 19 and 20, the central element 65 comprises holes 21 for accommodating corresponding permanent magnets 20. There may be two holes 21, as shown, disposed symmetrically on either side of the center of the element 65. The ring-shape element 66 comprises, at a section where the central element 65 joins the ring-shaped element 66, a stabilization slot 68. The slot 68 allows passage of a string of etching solution from under the ring-shape element 66 so as to create a stabilizing flow to lift and stabilize body 6. The ring-shaped element 66 preferably has a height of around 20 mm, for example between 15 and 25 mm. This helps reduce the weight of the body, thus facilitating the rotational movement.

In this embodiment, the base element 31 comprises two arms 30 intersecting at their mid-length and forming a cross concentric with the body 6. The length L of each arm 30 is substantially equal to the outer diameter of the ring-shaped element 66. In the illustrated embodiment, each arm 30 has, when viewed along a longitudinal direction thereof, a rectangular cross section with a large side parallel to the plane along which the ring-shaped element 66 extends.

As illustrated in FIGS. 19 and 20, each half 75 of an arm 30 comprises a hole 25 for receiving a corresponding permanent magnet 60. The holes 25 on a same arm 30 are positioned symmetrically with regard to the center C of the base element 31.

The magnets 20 received by the central element 65 are mainly responsible for the rotational movement of the magnetic support device. The magnets 20 preferably have a diameter ranging from 4 to 8 mm, for example around 6 mm, and are capable of holding a weight of around 1 kg, for example between 1 and 1.5 kg.

The magnets 60 received in the base element 31 are mainly responsible for the attraction of the base element 31 with other elements of the holding member, for example a wafer support 10 or a removable part 70, as explained further with respect to FIG. 24 and FIG. 28. These magnets 60 preferably have a diameter ranging from 2 to 4 mm, for example around 3 mm, and are capable of holding a weight of 1 kg.

The magnets 20, 60 may have a circular cross section. In a variant, the magnets have a substantially parallelepipedal shape, as illustrated in FIG. 33.

The base element 31 is fixed to the ring-shape element 66, for example by screwing, at end portions 77 thereof. The end portions 77 comprise protrusions 93 that abut against the upper surface of the ring-shaped element 66.

As illustrated in FIG. 20(b), the base element 31 may form an angle β with the body 6, β preferably ranging between 1° et 3°, for example of 2°. Angles of the above value allow reducing the risk of destabilizing the body 6.

In the embodiments of FIGS. 21 to 23, disc shaped substrates W having different diameters are held above the base element 31 by gripping means 32, 44. The diameters of the wafers are smaller than that of the ring-shaped element 66.

In the variants illustrated in FIG. 21 and FIG. 22, the wafer W is held at it peripheral edge by four gripping elements 32 or pins 44 to both arms 30 of the base element 31. In the variant illustrated in FIG. 23, the wafer W is held to one arm 30 of the base element 31 by two gripping elements 32. The gripping elements 32 abut respectively against an end portion 77 of the corresponding arm 30 and against the other arm 30 in the zone where the arms intersect.

The base element 31 may comprise holes 62 for immobilizing the gripping elements 32 or pins 44 at predefined positions, as visible in FIG. 20(a). The holes 62 may be provided on each half 75 of an arm 30, both at an end portion 77 thereof, and between the end portion 77 and the adjacent hole 25. The holes 62 on a same arm 30 are situated symmetrically with regard to the center C of the base element 31.

The gripping elements 32 may be fixed to the base element 31 by snap-fastening. Each gripping element 32 may have a general U shape as shown in FIG. 21(a).

More specifically, in the embodiment of FIGS. 21 and 21(a), the gripping elements 32 have a top wall 82 and two legs 81 connected to respective ends of the top wall 82. The legs 81 comprise, at their free ends, ribs 83 that allow the gripping element 32 to be fixed to the base element 31 by snap fastening and friction. A protrusion 80, configured to be received in a corresponding hole 62 of the base element 31, is formed under the top wall 82. The top wall 82 forms with respective legs 81 a notch 100 configured for engaging the wafer.

In the variant illustrated in FIG. 22, the gripping means may take the form of pins 44 engaged in the holes 62 at end portions 77 of the arms 30. The pins 44 have, as shown in FIG. 22(a), bodies 86 configured for insertion in the holes 62 and enlarged heads 87 that cover the wafer, as shown, to hold it in place on the arms 30.

In the embodiment of FIG. 24, the wafer W has a diameter greater than that of the ring-shaped element 66. The holding member 3 further comprises a wafer support 10 configured for being fixed to the base element 31 by magnetic forces and to which the wafer W is fixed.

As shown in FIGS. 24 and 25, the wafer support 10 has a cross-shaped body comprising two arms 17 of equal length. The length of the arms 17 is larger than the diameter of the wafer W to be etched. Magnets 60 are fixed to a bottom surface of the wafer support 10. These magnets 60 are situated on the wafer support 10 so as to face corresponding magnets 60 of the base element 31 when the wafer support 10 is superposed to the base element 31. In this way, the wafer support 10 is attracted to the base element 31 by magnetic attraction and thus rotates solidly with the base element 31.

In the embodiment of FIG. 25, the wafer W is held at its peripheral edge by four pins 44. The pins 44 are fixed to the end portions 78 of each arm 17 of the wafer support 10.

In the variant illustrated in FIG. 26(a) and FIG. 26(b), the wafer support 10 further comprises a connecting ring 71 that connects the arms 17 of the wafer support 10 substantially at mid-length thereof. This helps to improve the rigidity of the wafer support 10.

The support 10 comprises, at three respective end portions 78 of the arms 17, gripping protrusions 88. Each protrusion 88 extends along an angle γ with the wafer support 10 and defines a notch against the bottom of which the wafer can abut.

The remaining half of the arm not provided with a corresponding protrusion is configured to allow a gripping insert 90 to be fixed thereon. In the shown example, this arm half comprises a hole 72 for fixing the gripping insert 90.

As can be seen in FIGS. 27(a) and 27(b), the gripping insert 90 comprises a head 91 having a non-circular cross section helping to turn it. The gripping insert 90 comprises a cylindrical bottom portion 92 configured to be force fitted in the hole 72. The gripping insert 90 further comprises, between the head 91 and bottom portion 92, a flange 92 having on its lower side a shoulder 94 of circular outline. The longitudinal axis of the bottom portion 92 is offset with respect to the center of the shoulder 94.

In use, the wafer W is first positioned against the gripping protrusions 88. The gripping insert 90 is then introduced into the hole 72 and the flange 92 covers the peripheral edge of the wafer W. The member 90 can be turned so that the shoulder 94 abuts against the edge of the wafer and immobilizes it.

As shown in FIG. 23, the central rod 65 may comprise protective covers 22, for example in the same material as the body 6, that can be snap-fastened into the central element 62 in order to protect the magnets 20 received therein. Protective covers 22 may also be provided on the arms of the base element 31, for example at a bottom face thereof, as shown in FIG. 25.

The magnetic supporting device may comprise at least a removable part 70 configured for holding a test substrate T during the etching process, as shown in FIGS. 28 to 32. The removable part 70 comprises a vertical handle 71 attached at its lower end to a socket 72.

In the embodiment illustrated in FIGS. 28 to 30, the socket 72 comprises a hole 73 for receiving a magnet 60. The socket 72 has an elongate shape with a length e smaller than half of the length L of the arms 30. The socket preferably has a width d smaller than or same as that of the arms 30. The hole 73 is disposed in such a manner that when the handle 71 is arranged substantially above an end portion 77 of an arm 30, the magnetic disk 60 received in the hole 73 faces substantially the magnet 60 present in the corresponding half 75 of the arm 30. In this way, the socket 72 is held by magnetic attraction on the base element 31 during the etching process.

In use, a test substrate T is fixed to the removable part 70 via gripping means 32. The removable part 70 is introduced in the etching solution in which the base element 31 holding the substrate W to be etched is placed and attracted thereto by magnetic force. When the magnetic agitator is turned on, the test substrate T rotates at the same speed as the substrate W held on the base element 31.

In order to check the progress of the etching, the user may turn off the agitator, for example by a few seconds, and withdraw the test substrate T from the etching solution via the handle 71. The use of a magnetic force to fix the removable part 70 to the base element 31 allows removal of the removable part 70 to be performed in a rapid and smooth way without friction between different parts of the device. The removable part 70 can be detached from the base element 31 by a simple rotational movement around an axis passing by the intersection of the socket 72 and the handle 71 and perpendicular to a main plan N of the removable part. The attractive force between the removable part 70 and the base element 31 is chosen to ensure that withdrawal of the removable part 70 does not result in withdrawal of the base element 31 and body 6, which remain in the etching solution. The magnet 60 received in the removable part 70 may have a same or similar dimension and force of traction as those received in the base element 31. For example, the magnets 60 are capable of holding a weight of around 0.15 kg.

After analysis of the test substrate T, the latter may be reintroduced into the etching solution via the removable part 70 if necessary. Withdrawal of the removable part 70 can be performed on a regular basis during the etching process.

In the embodiment illustrated in FIGS. 31 and 32, the socket 72 comprises two holes 73 spaced apart in a direction along the length e of the socket 72. A magnet 60 can be received in one of the holes 73.

In the device illustrated in FIG. 32, four removable parts 70 are arranged each above a corresponding arm 30. A magnet 60 is received in each removable part 70, in the hole 73 closer to the vertical handle 71. The socket 72 of the removable parts 70 is oriented with the handle 71 towards the center C of the base element 31. The socket 72 forms an angle with the corresponding arm 30 so that a free end 76 of the socket 72 does not protrude beyond the ring-shaped element 66 in a main plan M of the body 6.

The socket 72 may comprise as shown in FIG. 31 on its lower face a blocker 79 in the form of a protrusion having a height between 0.5 and 2 mm, for example of about 1 mm. The blocker 79 may take support against a longitudinal side surface of the corresponding arm 30 when the device is in rotation. This helps to counteract the viscosity of the fluid on the removable part 70 and thus block possible rotational movement of the removable part 70 relative to the base element 31.

During the etching, the removable parts 70 can be removed one by one, for example on a regular basis.

In the variants illustrated in FIG. 41 and 42, the removable part 70 comprises a gripping part 7 at a free end of the handle 71. The gripping part 7 has a diameter that is larger than that of the handle 71. The etching solution, for example a KOH solution with a concentration of 45%, makes the objects in contact therewith slippery and thus difficult to grip. The presence of the gripping part 7 facilitates the gripping of the removable part 70 during the etching.

The removable part 70 may comprise an identification element 99, as illustrated in FIG. 42 and FIGS. 43(a) to (d). The identification element 99 is arranged above the gripping part 7 and comprises an element with an identifiable shape, for example a geometrical shape as in the examples of FIG. 42 and FIGS. 43(a) to (d). This helps to identify the test substrates fixed on the different removable parts. In this way, the user may selectively withdraw and/or reintroduce a test substrate via the corresponding removable part 70 without confusion with other test substrates held by other removable parts 70.

The identification elements 99 may be of any shape that allows the user to differentiate the different removable parts 70. For example, the identification elements 9 may be in the form of letters or numbers.

In the variant illustrated in FIGS. 34 to 37, the body 6 further comprises a wall portion 63 that connects the ring-shaped element 66 to the base element 31. The wall portion 63 comprises concentric upper 67 and lower 69 rings of same dimension and connected to each other through four connecting elements 64 regularly arranged between the upper 67 and lower 69 rings. The presence of the wall portion 63 increases the stability of the rotational movement of the device; this allows to operate at a higher rotational speed and is more adapted to a wafer of larger dimension, for example with a diameter of more than 100 mm, or more than 125 mm, or even more than 150 mm.

In the embodiment illustrated, two opposite connecting elements 64 comprise each a hole 61 configured for insertion of a base element 31 in the form of a rod 33, as the one illustrated in the examples of FIGS. 2 and 4. When such a base element 31 in the form of a rod 33 is present, the cross-shaped base element 31 as illustrated in FIGS. 34 to 37 can be omitted.

The upper ring 67 comprises holes 48 for receiving the protrusions 93 of the base element 31. By properly choosing the height of the protrusions 93 and/or the depth of the holes 48, the base element 31 may form an angle β with the wall portion 63, preferably ranging between 2° et 4°. In a variant not illustrated, the base element 31 is fixed to the wall portion 63 by magnetic force. In another variant, the base element 31 is movable relative to the upper ring 67 so as to allow adjustment of the angle β.

The lower ring 69 comprises a groove 96 in which the ring-shaped element 66 is received. Two opposite connecting elements 64 are situated along the central rod 65.

In a variant, the wall portion 63 comprises a central bar 56 extending along a diameter of the lower ring 69, as in the embodiment of FIG. 38. The central bar 56 comprises holes 51 for receiving magnets 20, in the same way as the central rod of the ring-shaped element 66.

The substrate W is held to the base element by magnetic force via a wafer support 10 as described with regard to FIGS. 26(a) and (b). In a variant not illustrated, the wafer support 10 is fixed to the base element by friction.

In the variant illustrated in FIGS. 38 to 40, the wafer support 10 is fixed directly to the upper ring 69 by friction. Each half 19 of an arm 17 comprises a projection 18 projecting from a bottom face of the corresponding half 19 of the arm 17. The wafer support 10 comprises a fixing base 16 that extends from the projection 18 in a direction perpendicular to the main plan P of the wafer support. The fixing bases 16 are configured to be received in the holes 48. By properly choosing the height of the fixing base 16 and/or the depth of the holes 48, the wafer support may form an angle β with the wall portion 63, preferably ranging between 2° et 4°.

In a variant not illustrated, the base element 31 is integrally formed with the wall portion 63.

### EXAMPLES

### Example 1

A 2 L beaker containing 500 mL of water is heated at 75° C. 150 ml of 40% KOH solution is added to a 400 mL beaker, which is transferred to the 2 L beaker in order to be heated in water bath. Heating is kept until the temperature of the water in the 2 L beaker reaches 75° C. again.

The magnetic supporting device of FIG. 15 with the wafer W fixed thereon is then introduced in the 400 mL beaker with the wafer W facing upwards. Then the agitator is turned on at a speed of 150 rpm.

FIG. 17 is a picture taken with an electronic scanning microscope of the etched face of the wafer W thus obtained by the KOH attack at the end of 89 min (+/−60 seconds). A surface with homogeneously distributed microstructures M is obtained.

FIG. 18 (a) to (f) are pictures of microstructures M obtained by KOH attack on different silicon wafers (Si/SiO₂<100>).

In each case, a wafer comprising a homogeneous set of microstructures M is obtained.

### Example 2

Two substrates each of 1 cm² having followed UV photolithography are used. The UV photolithography was performed using respective masks with hexagonal networks as illustrated in FIGS. 44(a) and (b). The masks have respective patterns with a base having a diameter of 100 μm and an edge-to-edge distance of 33 μm and a base having a diameter of 75 μm and an edge-to-edge distance of 25 μm.

As illustrated in FIG. 45, the test substrates T are fixed to respective removable parts 70 of a supporting device as illustrated in FIG. 32.

Etching is performed with an etching solution of KOH having a concentration of 45% at 70° C., with the magnetic support device turning at a speed of 190 rpm.

The two test substrates T are respectively etched during 50 and 60 minutes. The results of etching are illustrated on FIGS. 46(a) to (d) and FIGS. 47(a) to (d) respectively.

Both test substrates show good homogeneity.

The invention is not limited to the embodiments described above.

For example, the magnetic rod may be fixed to a bottom wall of the device.

Holding members other than those described above may be used for holding one or more wafers with or without allowing relative movement between the wafers and the body of the device.

The device according to the invention may be used for etching silicon wafers for various applications, not only for preparing microneedles to treat worms. The device may also be used for etching substrate other than silicon substrates.

For example, the invention may be used in all industries wherein wet and chemical engraving of wafers, in particular by KOH, is performed following UV photolithography for creating microstructures thereon. Such industries may include among other electronics, for example for the production of printed circuit, or pharmaceutical industries wherein wafers with micro-needles thereon may be used.

1. A method of etching at least one substrate, in order to produce a grid of micro-protrusion, comprising disposing the at least one substrate on a magnetic supporting device, and driving, in an etching solution, the magnetic supporting device in rotation via a magnetic agitator external to the etching solution, so that the magnetic supporting device causes the at least one substrate to rotate at least in a same direction as the magnetic supporting device.

2. (canceled)

3. The method of claim 1, wherein the at least one substrate does not rotate relative to the magnetic supporting device during the etching.

4. The method of claim 1, wherein the at least one substrate is disposed with a main face oriented perpendicular to an axis around which the magnetic supporting device rotates.

5. The method of claim 1, wherein the at least one substrate and the magnetic supporting device are configured to allow setting the orientation of the at least one substrate relative to the magnetic supporting device.

6. The method of claim 1, the magnetic supporting device comprising a removable part that can be withdrawn from the etching solution without withdrawal of the at least one substrate to be etched, the method comprising disposing a test substrate on the removable part which is withdrawn from the etching solution, during the etching process.

7. A system comprising:
a magnetic agitator
a magnetic supporting device configured for receiving at least one substrate (W) to be etched in an etching solution, in a predefined configuration relative to the magnetic supporting device, so that when the magnetic supporting device is driven in rotation by the magnetic agitator the substrate rotates in a same direction as the supporting device.

8-9. (canceled)

10. A magnetic supporting device comprising:
a body,
at least one holding member for holding at least one substrate in a predefined position relative to the body,
at least one magnet fixed relative to the body.

11. The magnetic support device of claim 10, configured for holding, individually or simultaneously, substrates of different dimensions.

12-14. (canceled)

15. The magnetic supporting device of claim 10, the at least one holding member comprising a base element for supporting the at least one substrate and gripping means configured for holding the at least one substrate onto the base element.

16. The magnetic supporting device of claim 10, the at least one holding member comprising a rotational support configured to allow rotation of the holding member relative to the body.

17. The magnetic supporting device of claim 16, the at least one holding member being configured to allow setting orientation of the at least one substrate around an axis perpendicular to an axis around which the magnetic supporting device rotates.

18. The magnetic supporting device of claim 10, the body being of a ring shape around an axis.

19. The magnetic supporting device of claim 15, the body comprising a ring-shaped element at its periphery and a central element formed integrally with the ring-shaped element and extending along a diameter of the body, the central element comprising holes for accommodating corresponding permanent magnets.

20. The magnetic supporting device of claim 19, the base element comprising two arms intersecting at their mid-length and forming a cross concentric with the body.

21. The magnetic supporting device of claim 20, each half of the arms comprising a hole for receiving a corresponding permanent magnet.

22-24. (canceled)

25. The magnetic supporting device of claim 10, the holding member comprising a wafer support configured for being fixed to the base element by magnetic forces and to which the at least one substrate is fixed, magnets being fixed to a bottom surface of the wafer support.

26. (canceled)

27. The magnetic supporting device of claim 25, the wafer support having a cross-shaped body.

28. The magnetic supporting device according to claim 10, comprising at least one removable part that can be withdrawn from the etching solution during etching of the at least one substrate, the at least one removable part being configured for holding a test substrate and comprising at least one magnet.

29. (canceled)

30. The magnetic supporting device according to claim 28, the at least one removable part being fixed to the base element by magnetic force, the at least one removable part comprising a handle and a socket.

31-32. (canceled)

33. The magnetic supporting device according to claim 10, the at least one holding member comprising gripping means for holding substrates of different dimensions.
